(19) United States
(12) Patent Application Publication
(10) Pub. No.: US 2024/0418645 A1
(43) Pub. Date: Dec. 19, 2024

(54) SEMICONDUCTOR MEASUREMENT APPARATUS

(71) Applicant: SAMSUNG ELECTRONICS CO., LTD., Suwon-si (KR)

(72) Inventors: Hojun Lee, Suwon-si (KR); Jangwoon Sung, Suwon-si (KR); Wookrae Kim, Suwon-si (KR); Hyungjin Kim, Suwon-si (KR); Seungbeom Park, Suwon-si (KR); Junho Shin, Suwon-si (KR); Myungjun Lee, Suwon-si (KR)

(21) Appl. No.: 18/408,247

(22) Filed: Jan. 9, 2024

(30) Foreign Application Priority Data
Jun. 19, 2023 (KR) 10-2023-0078222

(51) Int. Cl. G01N 21/47; H01L 21/66; G01N 21/17

(52) U.S. Cl. CPC G01N 21/4788; H01L 22/12; G01N 2021/1748; G01N 2021/1765; G01N 2021/479; G01N 2201/06113; G01N 2201/0636

(57) ABSTRACT

An example semiconductor measurement apparatus includes a light source, a pattern generator, a stage, an image sensor, and a controller. The light source is configured to output light in a predetermined wavelength band. The pattern generator is configured to generate light including a speckle pattern by scattering the light output from the light source. The stage is disposed on a movement path of the light including the speckle pattern, and a sample reflecting the light including the speckle pattern is seated on the stage. The image sensor is configured to receive light reflected from the sample and generate an original image representing a diffractive pattern of light reflected from the sample. The controller is configured to generate a prediction image for estimating diffractive characteristics of light incident on the image sensor.

### CROSS-REFERENCE TO RELATED APPLICATION

This application claims benefit of priority to Korean Patent Application No. 10-2023-0078222 filed on Jun. 19, 2023, in the Korean Intellectual Property Office, the disclosure of which is incorporated herein by reference in its entirety.

### BACKGROUND

A semiconductor measurement apparatus may be an apparatus configured to measure critical dimensions of patterns in a sample subjected to a semiconductor process, and recently, a measurement apparatus, which can not only measure critical dimensions but also capture images of actual shapes of patterns formed in the sample, has been proposed. In this manner, a measurement apparatus configured to capture an image of the actual shape of the patterns may inspect a structure and a shape of the patterns in a non-destructive manner, but there may be a problem that an angle of view and a resolution may be limited, and in a trade-off relationship, it may be difficult to improve the efficiency and accuracy of an inspection operation.

### SUMMARY

The present disclosure relates to semiconductor measurement apparatuses, including a semiconductor measurement apparatus for improving both an angle of view and resolution by restoring an image representing a measurement region irradiated with light from a sample using an image obtained by irradiating the sample with light including a speckle pattern.

In general, according to some aspects, the subject matter of the present disclosure relates to a semiconductor measurement apparatus including: a light source configured to output light in a predetermined wavelength band; a pattern generator configured to generate light including a speckle pattern by scattering the light output from the light source; a stage disposed on a movement path of the light including the speckle pattern and in which a sample reflecting the light including the speckle pattern is seated; an image sensor configured to receive light reflected from the sample and generate an original image representing a diffractive pattern of light reflected from the sample; and a controller configured to generate a prediction image for estimating diffractive characteristics of light incident on the image sensor, using a first optical model representing optical characteristics of the light including the speckle pattern and a second optical model representing optical characteristics of a measurement region of the sample for reflecting the light including the speckle pattern, wherein the controller compares the prediction image with the original image and generates a result image representing the measurement region.

In general, according to some other aspects, the subject matter of the present disclosure relates to a semiconductor measurement apparatus including: a light source configured to output coherent light; a pattern generator configured to emit light including a plurality of planar waves moving in different directions to a sample by scattering the coherent light; a stage configured to adjust a position of the sample so that light is reflected in a selection region which is a partial region of the sample; and an image sensor configured to generate an original image in response to light reflected from the selection region.

In general, according to some other aspects, the subject matter of the present disclosure relates to a semiconductor measurement apparatus including: a speckle lighting configured to output light including a plurality of planar waves moving in different directions; a stage in which a sample for reflecting the light output from the speckle lighting is disposed; an image sensor configured to generate an original image in response to light reflected from a partial region of the sample; and a controller configured to generate a prediction image for estimating a diffractive pattern of light incident on the image sensor, by executing a forward propagation operation with a first optical model representing optical characteristics of light output by the speckle lighting, and a second optical model representing the optical characteristics of the light reflected from the sample, wherein the controller is configured to execute a backward propagation operation for adjusting the first optical model and the second optical model based on a difference between the prediction image and the original image, and obtain a result image representing the partial region of the sample by repeatedly executing the forward propagation operation and the backward propagation operation.

In some implementations, coherent light is irradiated to a pattern generator to generate light including a speckle pattern, and the light including the speckle pattern is irradiated to a sample and then incident on an image sensor. Since light reflected and scattered from the pattern generator is irradiated to the sample and then incident on an image sensor, an area of a region in which light is irradiated in a single capturing operation is increased to enhance the efficiency of an inspection operation. Furthermore, an original image generated by the image sensor is compared with a prediction image for estimating a diffractive pattern of light incident on the image sensor to generate a resulting image for displaying a region to which light is irradiated, thereby improving the accuracy of the inspection operation by improving a resolution of the result image.

Advantages and effects of the present application are not limited to the foregoing content and may be more easily understood in the process of describing some implementations of the present disclosure.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 is a view schematically illustrating a semiconductor measurement apparatus according to an example implementation of the present disclosure.

FIG. 2 is a flowchart illustrating an inspection method using a semiconductor measurement apparatus according to an example implementation of the present disclosure.

FIG. 3 is a view illustrating an operation of a semiconductor measurement apparatus according to an example implementation of the present disclosure.

FIGS. 4 and 5 are views illustrating an operation of a semiconductor measurement apparatus according to an example implementation of the present disclosure.

FIG. 6 is a view illustrating optical characteristics of a pattern generator included in a semiconductor measurement apparatus according to an example implementation of the present disclosure.

FIG. 7 is a view illustrating an operation of a semiconductor measurement apparatus according to an example implementation of the present disclosure.

FIG. 8 is a flowchart illustrating an operation of a semiconductor measurement apparatus according to an example implementation of the present disclosure.

FIG. 9 is a view illustrating an operation of a semiconductor measurement apparatus according to an example implementation of the present disclosure.

FIGS. 10 and 11 are views illustrating operations of a semiconductor measurement apparatus according to an example implementation of the present disclosure.

FIGS. 12 and 13 are views illustrating operations of a semiconductor measurement apparatus according to an example implementation of the present disclosure.

FIGS. 14 to 16 are views illustrating operations of a semiconductor measurement apparatus according to an example implementation of the present disclosure.

FIGS. 17 and 18 are views illustrating semiconductor devices to which an inspection operation using a semiconductor measurement apparatus according to an example implementation of the present disclosure may be applied.

### DETAILED DESCRIPTION

Hereinafter, example implementations of the present disclosure will be described with reference to the accompanying drawings.

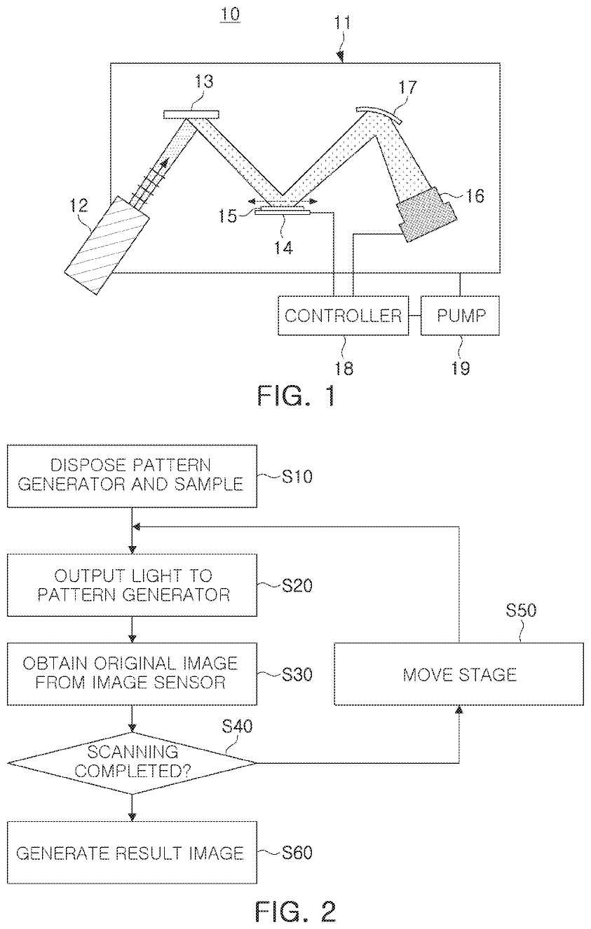

FIG. 1 is a view schematically illustrating a semiconductor measurement apparatus according to an example implementation of the present disclosure.

Referring to FIG. 1, a semiconductor measurement apparatus 10 according to an example implementation of the present disclosure includes a light source 12, a pattern generator 13, a stage 14, an image sensor 16, and a controller 18. The light source 12 outputs light in a predetermined wavelength band, and may output light such as an extreme ultraviolet wavelength band, an ultraviolet wavelength band, and a visible light wavelength band. According to an example implementation, the light source 12 includes a plurality of light sources emitting light having different wavelength bands.

For example, when the light source 12 outputs light in the extreme ultraviolet wavelength band, the light source 12 may output extreme ultraviolet light having a high energy density in a wavelength band of 13.5 nm. In this case, the light source 12 may include a plasma-based light source or a synchrotron radiation light source. The plasma-based light source refers to a light source that generates plasma and uses light emitted by the plasma, and may include a laser-produced plasma (LP) light source or a discharge-produced plasma (DPP) light source. For example, when the light source 12 includes a plasma-based light source, the light source 12 may include a condensing mirror such as an elliptical mirror or a spherical mirror, in order to increase energy density of extreme ultraviolet light.

The light output from the light source 12 may be coherent light. Referring to FIG. 1, the light source 12 may output light having high spatial coherence by aligning a wave front. The light output by the light source 12 may be reflected and/or scattered by the pattern generator 13, and for example, the light reflected by the pattern generator 13 may include a speckle pattern. The pattern generator 13 may include at least one of a diffractive optical element, an optical lattice structure, a scattering element, and a wavefront modulator.

Light reflected by the pattern generator 13 may be incident on a sample 15 disposed on the stage 14. For example, the sample 15 may be a wafer or a mask in which a predetermined pattern is formed, and optical characteristics of light reflected from the sample 15 may vary depending on the shape and size of the patterns formed in the sample 15. The light reflected from the sample 15 may be incident on the image sensor 16, and in an example implementation illustrated in FIG. 1, a mirror 17 may be further disposed between the stage 14 in which the sample 15 is disposed, and the image sensor 16.

The image sensor 16 may generate an original image in response to the light reflected from the sample 15. For example, the original image may be an image representing a diffractive pattern of the light reflected from the sample 15 and incident on the image sensor 16.

The controller 18 may control operations of the light source 12, the stage 14, and the image sensor 16. For example, the controller 18 may control the light source 12 to output coherent light and move the stage 14 so that the light reflected and scattered by the pattern generator 13 is reflected in a specific region of the sample 15. In an example implementation, the controller 18 may specify, in the sample 15, a measurement region to generate an image representing a shape of a pattern, and divide the measurement region into a plurality of unit regions. At least some of the plurality of unit regions may be defined to overlap each other, and the controller 18 may move the stage 14 so that light is irradiated to the plurality of unit regions at least once. The image sensor 16 may generate at least one original image for each of the plurality of unit regions.

The controller 18 may generate a first optical model representing the optical characteristics of light emitted by the pattern generator 13 and a second optical model representing the optical characteristics of the measurement region reflecting light from the sample 15. The controller 18 may generate a prediction image for estimating diffractive characteristics of light incident on the image sensor by executing an arithmetic operation using the first optical model and the second optical model.

When the image sensor 16 generates an original image for the measurement region irradiated with light in the sample 15, the controller 18 may adjust the first optical model and the second optical model by comparing the prediction image with the original image. For example, initial values of each of the first optical model and the second optical model may be arbitrarily determined. The controller 18 may update the prediction image with the first optical model and the second optical model adjusted based on comparison results of the prediction image and the original image, compare the updated prediction image with the original image, and repeat an operation of adjusting the first optical model and the second optical model.

When the adjusting operation is completed to optimize the first optical model and the second optical model, the controller 18 may generate a result image representing the measurement region in which light is reflected from the sample 15, using the optimized first optical model and the optimized second optical model. The result image may be an image representing patterns of the measurement region, and a shape and a critical dimension of the pattern may be determined using the result image.

Referring to FIG. 1, the pattern generator 13, the stage 14, and the image sensor 16 may be disposed in a housing 11, and accordingly, the light output from the light source 12 may move in the housing 11. According to an example implementation, the light source 12 may also be disposed in the housing 11. For example, an internal space of the housing 11 may be depressurized to a vacuum state by the pump 19. A pump 19 may be operated by the controller 18, and the internal space of the housing 11 may be depressurized with the pump 19 to minimize scattering by air, thereby increasing accuracy of a measurement operation. However, an operation of the pump 19 may not completely set the internal space of the housing 11 to a vacuum state without air, and for example, the pump 19 may operate to reduce the pressure inside the housing 11 by a predetermined reference air pressure or less.

Meanwhile, according to an example implementation, the semiconductor measurement apparatus 10 may be implemented in a transmission type different from the reflection type illustrated in FIG. 1. In this case, light emitted from the light source may pass through the pattern generator and may be incident on the sample, and may pass through the sample and may be incident on the image sensor.

FIG. 2 is a flowchart illustrating an inspection method using a semiconductor measurement apparatus according to an example implementation of the present disclosure.

Referring to FIG. 2, an inspection method according to an example implementation of the present disclosure begins by arranging a pattern generator and a sample (S10). As described above with reference to FIG. 1, a sample is disposed on a stage, and a pattern generator is disposed between the sample and a light source, thus reflecting or transmitting light output from the light source and moving the light to the sample. A controller of a semiconductor measurement apparatus adjusts a position of the stage in order to irradiate light reflected and/or scattered from the pattern generator, to a measurement region in which a pattern to be inspected is disposed.

When a sample arrangement and a position adjustment of the stage are completed, the controller may control the light source so that light is output to the pattern generator (S20). The light source may output coherent light, and the pattern generator may reflect and/or scatter the coherent light to emit light including a speckle pattern. For example, the light reflected by the pattern generator includes a plurality of planar waves moving in different directions, and the plurality of planar waves may have different phases. Accordingly, the light source and the pattern generator may be defined as speckle lighting.

The light reflected and/or scattered from the pattern generator may be incident on an image sensor, and the controller may obtain an image from the image sensor (S30). The original image may be an image representing diffractive characteristics of light incident on the image sensor.

For example, when an area of the measurement region is too large and it is difficult to capture an image with the light reflected and/or scattered from the pattern generator at once, the controller may divide the measurement region into a plurality of unit regions, may irradiate light to each of the plurality of unit regions, and may proceed with the capturing with the image sensor. During the capturing process, the controller may determine whether a scan for the plurality of unit regions is completed (S40). When a capturing operation is executed at least once for each of the plurality of unit regions, the controller may determine that the scan is completed.

When it is determined that the scan is not completed in operation S40, the controller may move the stage (S50), may irradiate the sample with light again, and may obtain an original image from the image sensor (S30). Meanwhile, when it is determined that the scan is completed in operation S40, the controller may generate a result image (S60). As described above, the result image may be generated by comparing the original image obtained by the controller from the image sensor with a prediction image generated by the controller through an arithmetic operation.

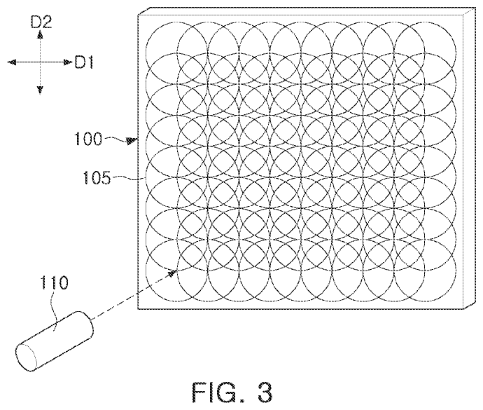

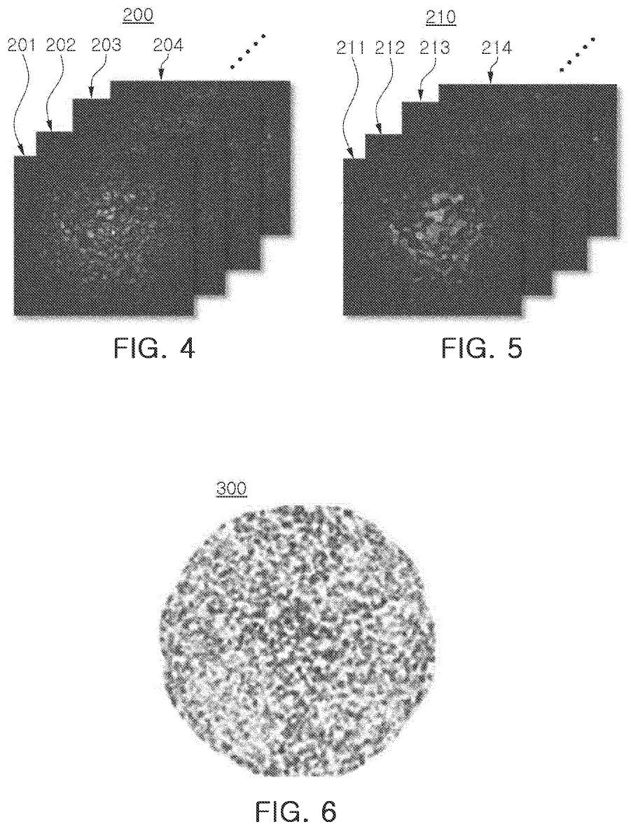

FIG. 3 is a view illustrating an operation of a semiconductor measurement apparatus according to an example implementation of the present disclosure. Meanwhile, FIGS. 4 and 5 are views illustrating an operation of a semiconductor measurement apparatus according to an example implementation of the present disclosure.

First, referring to FIG. 3, a plurality of unit regions 105 is defined in a sample 100. Each of the plurality of unit regions 105 may have an area in which light output from a speckle lighting 110 may be irradiated at once. As described above, the speckle lighting 110 may include a light source for outputting coherent light, and a pattern generator for reflecting and scattering the coherent light. Accordingly, the light output by the speckle lighting 110 includes a speckle pattern and may be comprised of a plurality of planar waves moving in different directions. The plurality of unit regions 105 may be arranged in a first direction D1 and a second direction D2 in parallel with a surface of the sample 100.

As illustrated in FIG. 3, each of the plurality of unit regions 105 is defined to overlap the other at least one unit region 105 in at least one of the first direction D1 and the second direction D2. While the speckle lighting 110 irradiates light so that at least some of the plurality of unit regions 105 overlap with each other, the controller obtains a plurality of original images 200 (201 to 204) from the image sensor, as illustrated in FIG. 4. For example, the number of the plurality of original images 200 may be equal to the number of the plurality of unit regions 105.

Each of the plurality of original images 200 may be compared with each of a plurality of prediction images 210 (211 to 214). Each of the plurality of prediction images 210 may be an image that predicts a diffractive pattern of light output from the speckle lighting 110 and reflected from the sample 100 to be incident on the image sensor. For example, the plurality of prediction images 210 may be generated using a first optical model representing optical characteristics of the light output by the speckle lighting 110 and the second optical model representing the optical characteristics of each of the unit regions 105 for reflecting light from the sample 100. Accordingly, as the first optical model and the second optical model are more accurate, a difference between the plurality of prediction images 210 and the plurality of original images 200 may be reduced.

The plurality of prediction images 210 may be generated for the plurality of unit regions 105 defined in the sample 100. For example, a first prediction image 211 generated for a first unit region among the plurality of unit regions 105 may be compared with a first original image 201 generated by the image sensor when light reflected from the first unit region is incident on the image sensor. Similarly, a second prediction image 212 corresponding to a second unit region may be compared with a second original image 202 representing a diffractive pattern of light reflected from the second unit region.

The controller of the semiconductor measurement apparatus may adjust a first optical model and a second optical model until a difference between the plurality of original images 200 and the plurality of prediction images 210 is equal to or smaller than a predetermined reference difference. For example, the difference between the plurality of original images 200 and the plurality of prediction images 210 may be defined by fidelity. The fidelity is a parameter indicative of how similar each of the plurality of prediction images 210 is to the plurality of original images 200, and with a reduction in the fidelity, the prediction image 210 may be similar to the original image 200.

The controller may optimize the first optical model and the second optical model by adjusting the first optical model and the second optical model until the fidelity of the original image 200 and the prediction image 210 is equal to or smaller than the predetermined threshold value in each of the plurality of unit regions 105. When the optimization of the first optical model and the second optical model is completed, the optimized first optical model and the optimized second optical model may be used to generate result images representing the unit regions 105 of the sample 100, and based on the result images, patterns formed in the sample 100 may be inspected.

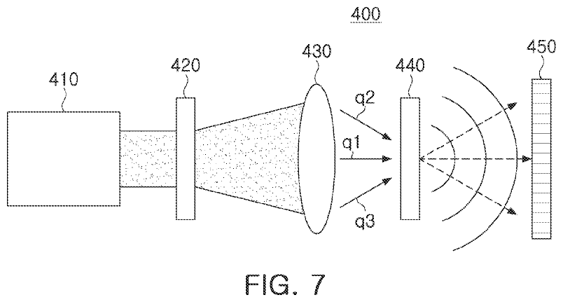

FIG. 6 is a view illustrating optical characteristics of a pattern generator included in a semiconductor measurement apparatus according to an example implementation of the present disclosure. Meanwhile, FIG. 7 is a view illustrating an operation of a semiconductor measurement apparatus according to an example implementation of the present disclosure.

FIG. 6 is a view illustrating a phase aberration in a region in which a pattern generator 300 according to an example implementation of the present disclosure transmits or reflects light received from a light source. Referring to FIG. 6, a phase difference between light incident on the pattern generator 300 and light emitted from the pattern generator 300 appears differently depending on a position of the pattern generator 300. Accordingly, light reflected from the pattern generator 300 or transmitted through the pattern generator 300 includes a plurality of planar waves moving in different directions.

FIG. 7 is a view simply illustrating a semiconductor measurement apparatus 400 according to an example implementation of the present disclosure. Referring to FIG. 7, the semiconductor measurement apparatus 400 includes a light source 410, a pattern generator 420, a lens 430, a sample 440, and an image sensor 450. In an example implementation illustrated in FIG. 7, the semiconductor measurement apparatus 400 is implemented in a transmission type.

The light source 410 may output light having coherence. The light output by the light source 410 may pass through the pattern generator 420, and the light passing through the pattern generator 420 may include a plurality of planar waves moving in different directions, as illustrated in FIG. 7. For example, at least some of the plurality of planar waves included in the light passing through the pattern generator 420 may have different phases.

The lens 430 may be disposed between the pattern generator 420 and the sample 440. The lens 430 may re-concentrate light spreading by passing through the pattern generator 420 and move the light to the sample 440. However, according to an example implementation, the lens 430 may be omitted.

The light passing through the lens 430 may be incident on the sample 440. Referring to FIG. 7, the light passing through the lens 430 may include a first planar wave q1, a second planar wave q2, and a third planar wave q3. However, this is an example implementation, and a larger number of planar waves may be included in the light incident on the sample 440. Light s incident on the sample 440 may be defined as any combination of a plurality of planar waves (q1, q2, . . . , qN) as in Equation 1 below. In Equation 1, α may be the intensity of each planar wave.

$$s = {α}_{1} q 1 + {α}_{2} q 2 + … + {α}_{N} qN \qquad < Equation 1 >$$

In other words, as the light output from the light source 410 passes through the pattern generator 420, first to third planar waves q1 to q3 moving in different directions may be incident on the sample 440. The first to third planar waves q1 to q3 moving in different directions may move in different directions as illustrated in FIG. 7 even after passing through the sample 440. Accordingly, in a single capturing operation, the image sensor 450 may receive light reflecting the optical characteristics of the sample 440 in a wider region, thereby increasing an angle of view of the semiconductor measurement apparatus 400.

In an example implementation, with a reduction of a grain size included in the pattern generator 420, a difference in a movement direction of the first to third planar waves q1 to q3, thereby allowing the light passing through the sample 440 to spread wider. Accordingly, according to the selection of the pattern generator 420, the angle of view of the semiconductor measurement apparatus 400 may be adjusted, and the efficiency of the inspection operation using the semiconductor measurement apparatus 400 may be improved.

Referring to FIG. 7, the first planar wave q1, the second planar wave q2, and the third planar wave q3 may all be incident on some of the pixels of the image sensor 450. An effective angle of view may be determined by a region NA in which pixels on which all of the first to third planar waves q1 to q3 are incident are disposed. The image sensor may generate an original image representing a diffractive pattern of light passing through the measurement region of the sample 440 based on a pixel signal generated by the pixels disposed in the region NA corresponding to the effective angle of view, and provide the original image to a controller of the semiconductor measurement apparatus 400.

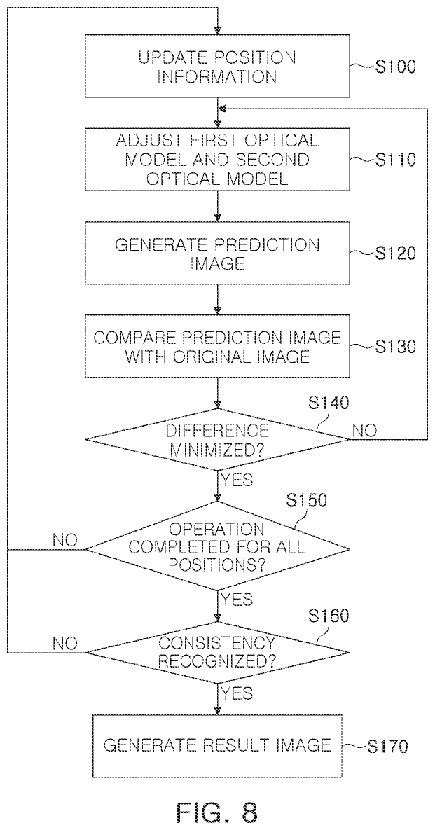

FIG. 8 is a flowchart illustrating an operation of a semiconductor measurement apparatus according to an example implementation of the present disclosure.

Referring to FIG. 8, an operation of the semiconductor measurement apparatus according to an example implementation of the present disclosure begins by allowing a controller of the semiconductor measurement apparatus to update position information (S100). The position information updated in operation S100 is position information of a region in which light is incident in the sample. As described above, the measurement region in which a pattern to be measured in the sample is formed may have a large area that may be difficult to cover with one capturing operation.

A controller may divide the measurement region into a plurality of unit regions, and may irradiate light at least once to each of the plurality of unit regions and adjust a position of a stage on which the sample is disposed so that an image sensor may obtain the original image for each of the plurality of unit regions. In operation S100, the position information may be updated by selecting one of the plurality of unit regions.

The light incident on each of the plurality of unit regions may be light output from a light source, reflected from a pattern generator, and then incident on a sample. A light source may output coherent light, and the pattern generator may reflect and scatter the coherent light and the coherent light may be decomposed into a plurality of planar waves having different directions and different phases. Accordingly, the light incident on the sample includes the plurality of planar waves, and may be light in which a speckle pattern appears.

When the position information is updated, the controller of the semiconductor measurement apparatus may adjust a first optical model and a second optical model (S110). The first optical model may be an optical model representing optical characteristics of light reflected from the pattern generator, and the second optical model may be an optical model representing optical characteristics of a unit region selected to update position information in operation S100. When there are no previously applied first and second optical models, that is, when the operation of the semiconductor measurement apparatus begins, the controller may generate the first optical model and the second optical model as any model.

The controller may generate a prediction image using the first optical model and the second optical model adjusted in operation S110 (S120). The prediction image may be an image obtained by estimating a diffractive pattern of light reflected from the pattern generator and the sample and then incident on the image sensor. For example, the controller may generate a prediction image by applying a convolution operation to the first optical model and the second optical model adjusted in operation S110.

When the prediction image is generated, the controller may compare the prediction image with the original image received from the image sensor (S130). The original image compared to the prediction image may be an image generated by the image sensor while light is irradiated to a unit region selected from the plurality of unit regions included in the sample, based on the position information updated in operation S100.

The controller may compare the prediction image with the original image, and determine whether a difference between the prediction image and the original image is minimal (S140). In an example implementation, the controller may calculate the difference between the prediction image and the original image using a cost function, for example, the cost function may be defined as illustrated in Equation 2 below.

$$arg {min}_{O , ψ} {‖ \sqrt{I} - \vert {H}_{z} ( ψ O ) \vert ‖}_{1} + λ {‖ ∇ O ‖}_{1} \qquad < Equation 2 >$$

In Equation 2 above, I is the original image, and ψ is a function representing the optical characteristics of the light reflected from the pattern generator and may correspond to the first optical model. On the other hand, O may correspond to a second optical model as a function of optical characteristics of a unit region on which light is actually irradiated and light is reflected among the plurality of unit regions included in the sample. The controller may adjust the first optical model and the second optical model until a difference between the prediction image and the original image as a result of a convolution operation of the first optical model and the second optical model is minimized (S110), may generate the prediction image (S120), and may repeatedly execute an operation of comparing the predicted image with the original image using the cost function (S130).

When the difference between the prediction image and the original image is minimized, the controller may determine whether the operation has been completed for all of the plurality of unit regions into which the measurement region to be inspected is divided in the sample (S150). When it is determined that there is a unit region that has not yet been calculated in operation S150, the position information may be updated (S100) to adjust a position of the stage on which the sample is seated, and operations S110 to S140 may be repeated.

When it is determined that the operation for all the unit regions has been completed in operation S150, the controller may determine whether consistency is recognized (S160). As described above with reference to FIG. 3, the plurality of unit regions into which the measurement region is divided in consideration of the angle of view of the image sensor may be defined so that at least some thereof overlap each other. The controller may determine whether prediction images corresponding to unit regions having overlapping regions are consistent with each other. In an example implementation, consistency may be defined as fidelity.

For example, when a first unit region and a second unit region overlap each other, the controller may determine the consistency between a first prediction image generated by applying arithmetic operations of operations S110 to S140 to the first unit region and a second prediction image generated by applying the arithmetic operations of operation S110 to S140 to the second unit region. Since the first unit region and the second unit region have overlapping areas, the first prediction image and the second prediction image may represent the same image in at least some regions.

When the consistency between the prediction images is not recognized in operation S160, the controller may determine that an optimization of the first optical model and the second optical model is not completed, and may repeat arithmetic operations of operations S100 to S150. On the other hand, when the consistency between the prediction images is recognized in operation S160, it may be determined that the optimization of the first optical model and the second optical model has been completed.

The controller may generate a result image using the optimized second optical model (S170). The optimized second optical model may be generated for each of the plurality of unit regions into which the measurement region is divided, and the controller may restore images of each of the plurality of unit regions using the optimized second optical model, and merge the images to generate a result image for the measurement region.

Accordingly, patterns included in the measurement region of the sample may be displayed on the result image. The controller may measure a shape and a critical dimension of the patterns included in the measurement region using the result image.

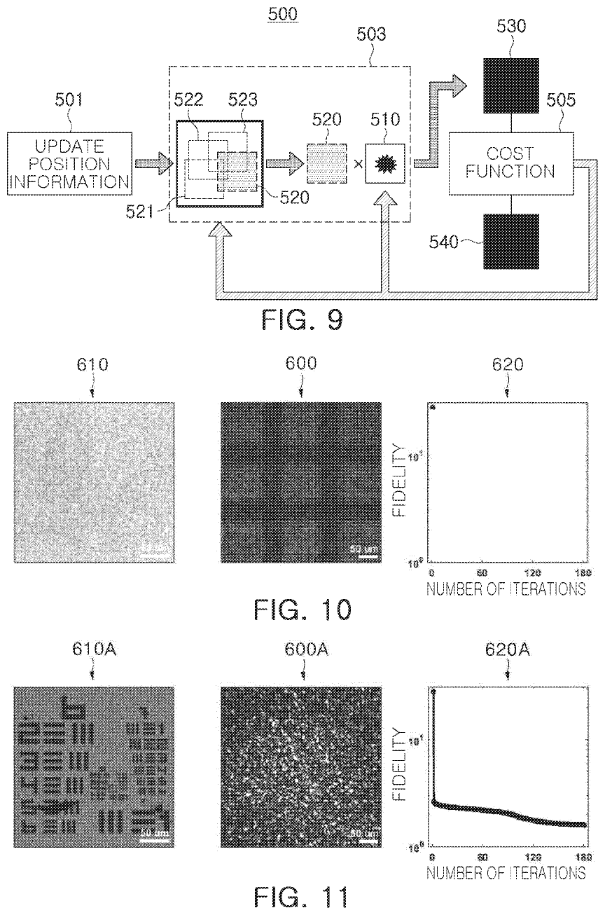

FIG. 9 is a view illustrating an operation of a semiconductor measurement apparatus according to an example implementation of the present disclosure.

Referring to FIG. 9, a controller of a semiconductor measurement apparatus 500 executes a first operation 501 for updating position information, a second operation 503 for generating a prediction image 530 using optical models 510 and 520, and a third operation 505 for comparing the prediction image 530 with an original image 540. When an operation of the semiconductor measurement apparatus 500 begins, the controller updates the position information by executing the first operation 501.

Based on the updated position information, the controller may move a stage on which a sample is seated, thus irradiating light to one of a plurality of unit regions included in a measurement region. For convenience of explanation below, it is assumed that light is irradiated to a first unit region, and accordingly, an image sensor may generate the original image 540 for the first unit region.

The controller may select one from a plurality of optical models for the plurality of unit regions based on the position information updated in the first operation 501. Referring to FIG. 9, the controller for the plurality of unit regions may include a plurality of second optical models 520 to 523. Since the image sensor generates the original image 540 for the first unit region by selecting the first unit region in the first operation 501, the controller can select a second optical model 520 corresponding to the first unit region.

The controller may generate the prediction image 530 for predicting a diffractive pattern of light reflected from the first unit region by executing a predetermined operation with a first optical model 510 and a second optical model 520. The prediction image 530 may be an image for estimating a diffractive pattern of light which is emitted from a light source and is reflected and/or transmitted from a pattern generator and a sample and is then incident on an image sensor. The controller may execute the third operation 505 for comparing the prediction image 530 with the original image 540, and for example, in the third operation 505, the prediction image 530 and the original image 540 may be compared using a cost function.

The controller may adjust the first optical model 510 and the second optical model 520 until a value of the cost function applied to the third operation 505 is minimized. In an example implementation of the present disclosure, the controller may generate a prediction image 530 by executing a forward propagation operation using the first optical model 510 and the second optical model 520. As described above, in a first forward propagation operation, the first optical model 510 and the second optical model 520 may be arbitrarily set, and for example, in the first optical model 510, amplitude modulation and phase aberration at each of a plurality of positions defined in a wavefront may be set to any value.

The prediction image 530 initially generated by the forward propagation operation may have a large difference from the original image 540 actually generated by the image sensor. In an example implementation of the present disclosure, a backward propagation operation may be executed using the difference between the original image and the prediction image. At least one of the first optical model 510 and the second optical model 520 may be adjusted by a back ward propagation operation.

When the backward propagation operation is completed, a new prediction image 530 may be generated by executing the forward wave operation using the adjusted optical models 510 and 520 again. The new prediction image 530 may be compared again with the original image 540, and the backward propagation operation based on the difference may be executed again. In this manner, the forward propagation operation and the backward propagation operation may be repeatedly executed. In an example implementation, the forward propagation operation and the backward propagation operation may be repeated until ae value of a cost function calculated from the prediction image 530 generated by the forward propagation operation and the original image 540 generated by the image sensor is minimized.

When the cost function has a minimum value and the prediction image 530 and the original image 540 match each other, a result image may be generated using the first optical model 510 and the second optical model 520 applied to the forward propagation operation that has generated the prediction image 530. For example, a wavefront image representing optical characteristics of the light incident on the sample may be generated using the first optical model 510. Meanwhile, the controller may generate an image representing patterns included in a unit region in which light is reflected from the sample using the second optical model 520.

When the prediction image 530 and the original image 540 match each other, the controller may re-operate the first operation 501 to update position information, and accordingly may move the stage on which the sample is seated, thus controlling light to be irradiated to other unit regions of the sample. For example, when the stage moves to allow light to be incident on a second unit region different from the first unit region, the image sensor may generate an original image 540 representing a diffractive pattern of light reflected from the second unit region.

The controller may select a second optical model 521 corresponding to the second unit region from the plurality of second optical models 520 to 523, and may generate a prediction image 530 for the second unit region using the second optical model 521 and the first optical model 510. For the second unit region, the controller may adjust the first optical model 510 and the second optical model 520 by repeating the backward propagation operation and the forward wave operation as described above until the prediction image 530 and the original image 540 match each other.

When the aforementioned operation is completed for all unit regions, the controller may obtain result images representing unit regions using optimized second optical models 520 to 523, and may combine the images to generate one result image representing the measurement region.

FIGS. 10 and 11 are views illustrating operations of a semiconductor measurement apparatus according to an example implementation of the present disclosure.

Each of FIGS. 10 and 11 may represent a fidelity graph according to the number of iterations of arithmetic operations and result images generated from each of a first optical model and a second optical model depending on the number of iterations of the forward propagation operation and the backward propagation operation described with reference to FIG. 9. In an example implementation described with reference to FIGS. 10 and 11, fidelity may be defined as Equation 3 below, and the forward propagation operation and the backward propagation operation may be repeatedly executed until the fidelity is equal to or smaller than a predetermined threshold value.

$$Fidelity = {log}_{10} {‖ \sqrt{I} - \vert {H}_{z} ( ψ O ) \vert ‖}_{2}^{2} \qquad < Equation 3 >$$

FIG. 10 illustrates result images 600 and 610 and a fidelity graph 620 in a state in which a forward propagation operation and a backward propagation operation are executed only once. For example, a first result image 600 is a wavefront image of light reflected from a pattern generator after being output from a light source, and a second result image 610 is an image representing some regions of a sample on which the light reflected from the pattern generator is incident. The first result image 600 is generated from a first optical model adjusted by executing the forward propagation operation and the backward propagation operation, and the second result image 610 is generated from a second optical model.

Since the forward propagation operation and the backward propagation operation have not been sufficiently repeated, the fidelity may have a very high value as illustrated in the fidelity graph 620. Furthermore, patterns formed in the sample may not be clearly displayed in the second result image 610.

FIG. 11 illustrates result images 600A and 610A and a fidelity graph 620A in a state in which a forward propagation operation and a backward propagation operation are repeatedly executed a sufficient number of times. By repeatedly executing the forward propagation operation and the backward propagation operation, the fidelity is reduced by a threshold value or less as illustrated in the fidelity graph 620A. Furthermore, a first optical model and a second optical model are adjusted while repeating the forward propagation operation and the backward propagation operation, and accordingly, a first result image 600A and a second result image 610A appears differently from those illustrated FIG. 10.

As illustrated in FIG. 11, in the first result image 600A generated using the first optical model, a speckle pattern included in light reflected from a pattern generator may be displayed. Meanwhile, in the second result image 610A generated using the second optical model, patterns formed on a sample may be displayed. In this manner, by using a semiconductor measurement apparatus according to an example implementation of the present disclosure, a result image representing an actual shape of patterns formed on a sample may be obtained, and based on the obtained result image, a shape and critical dimensions of the patterns may be accurately measured.

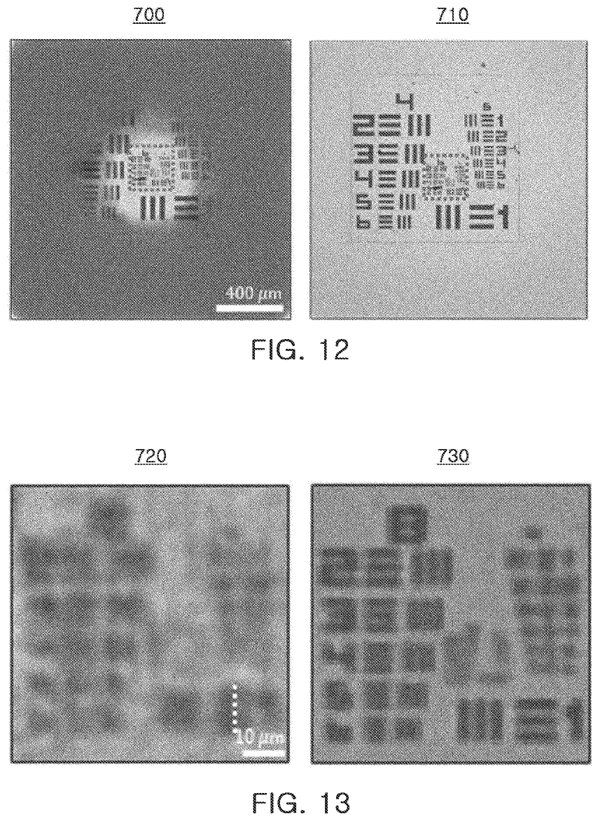

FIGS. 12 and 13 are views illustrating operations of a semiconductor measurement apparatus according to an example implementation of the present disclosure.

An image illustrated on a left side of each of FIGS. 12 and 13 may be an image of a sample restored in a first measurement method of irradiating the sample with coherent light output from a light source without a pattern generator. Meanwhile, an image illustrated on a right side of each of FIGS. 12 and 13 may be an image of the sample restored in a second measurement method of reflecting or transmitting the coherent light to the pattern generator and irradiating the sample with the coherent light. A semiconductor measurement apparatus according to some implementations of the present disclosure may use the second measurement method.

First, referring to FIG. 12, a first image 700 generated by the first measurement method has a relatively narrower angle of view than a second image 710 generated by the second measurement method. Accordingly, in an example implementation of the present disclosure using the second measurement method rather than the first measurement method, an image of a measurement region of the same area is obtained only by capturing fewer images.

Next, FIG. 13 is an enlarged view of region A disposed close to a central portion of each of a first image 700 and a second image 710. Referring to FIG. 13, a fourth image 730 enlarging region A in the second image 710 has a higher resolution than a third image 720 enlarging region A in the first image 700. Accordingly, in an example implementation of the present disclosure using a second measurement method rather than a first measurement method, a shape and critical dimensions of a pattern formed in a sample is more accurately inspected by obtaining a result image having a relatively higher resolution.

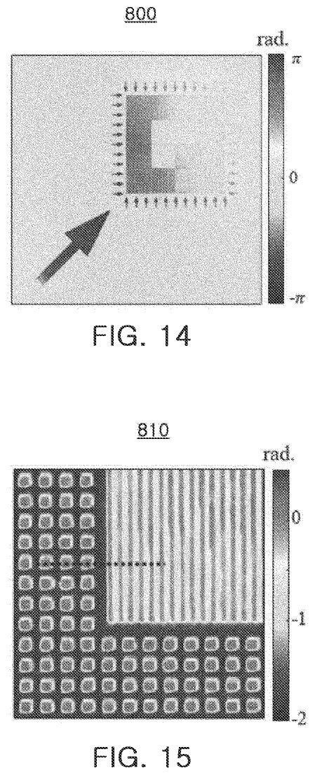

FIGS. 14 to 16 are views illustrating operations of a semiconductor measurement apparatus according to an example implementation of the present disclosure.

FIGS. 14 and 15 are views illustrating phase images 800 and 810 generated in a semiconductor measurement apparatus according to an example implementation of the present disclosure. For example, a first optical model and a second optical model are optimized by repeatedly executing a forward propagation operation and a backward propagation operation, and at least one of the optimized first optical model and the optimized second optical model is used to generate a phase image representing a phase difference of light reflected from the sample.

Referring to FIGS. 14 and 15, a phase difference within a region in which light is reflected from a sample is displayed on the phase images 800 and 810. Referring to a first phase image 800 and a second phase image 810, a phase difference varies depending on a height of the patterns formed in the sample and physical properties of the material constituting the patterns formed in the sample. For example, since a refractive index varies depending on the type of materials constituting the patterns formed in the sample, a phase difference therefrom occurs. Accordingly, the height of the patterns formed in the sample and the physical properties of the material included in the sample are known using the first phase image 800 and the second phase image 810.

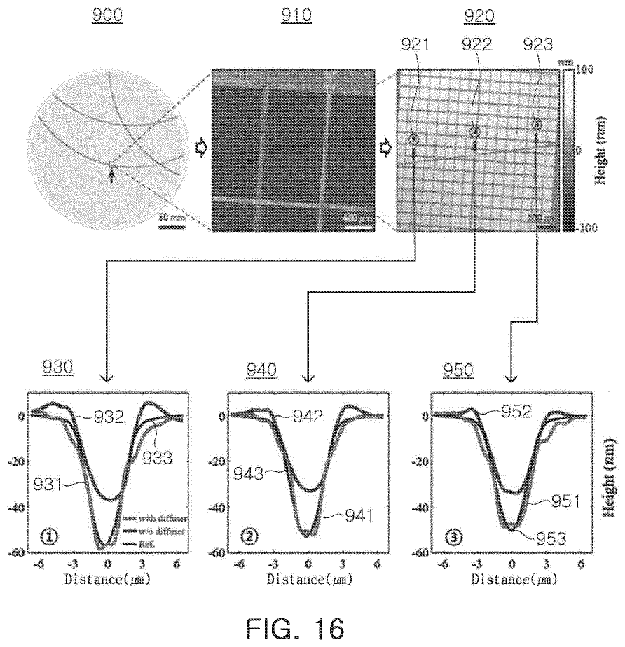

FIG. 16 is a view illustrating a result of measuring a depth of a groove present in a sample using a semiconductor measurement apparatus according to an example implementation of the present disclosure. Referring to FIG. 16, a groove is formed by generating a scratch in a partial region by applying a polishing process to a sample 900. In order to measure a depth of the groove formed in the sample 900, a semiconductor measurement apparatus according to an example implementation of the present disclosure irradiates light including a speckle pattern in a partial region of the sample 900 and generates an original image corresponding to the light reflected from the sample 900 with an image sensor.

As described above, the semiconductor measurement apparatus may generate a first optical model representing optical characteristics of the light including the speckle pattern and a second optical model representing the optical characteristics of the sample 900. The semiconductor measurement device may generate a prediction image with a first optical model and a second optical model, and may optimize the first optical model and the second optical model by repeatedly executing a forward propagation operation and a backward propagation operation, thereby restoring a result image 910 as illustrated in FIG. 16.

Next, a controller of the semiconductor measurement apparatus may separately obtain a phase image 920 for a partial region selected from the result image 910. A value of each pixel in the phase image 920 may be determined by a height of a pattern and a structure included in the sample 900, as previously described with reference to FIGS. 14 and 15, and in an example implementation illustrated in FIG. 16, a value of each pixel included in the phase image 920 may vary according to the depth of the groove generated during a polishing process.

Accordingly, in an example implementation of the present disclosure, first to third graphs 930 to 950 indicative of the depth of the groove existing in first to third positions 921 to 923, respectively, specified in the phase image 920, may be obtained. The first to third graphs 930 to 950 may display first measurement lines 931, 941 and 951 indicative of the depth of the groove determined according to the first measurement method, second measurement lines 932, 942 and 952 indicative of the depth of the groove determined according to the second measurement method, and reference lines 933, 943 and 953 indicative of the depth of an actually measured groove, respectively. The first measurement method may be a measurement method that directly irradiates coherent light to the sample, and the second measurement method may be a measurement method that irradiates light including a speckle pattern to the sample.

For example, referring to the first graph 930, the second measurement line 932 may be displayed as being more similar to the reference line 933 than the first measurement line 931. In this manner, in an example implementation of the present disclosure, the light including the speckle pattern may be irradiated to the sample, thereby accurately determining the depth of the groove included in the sample 900, the height of the pattern, and the material constituting the pattern.

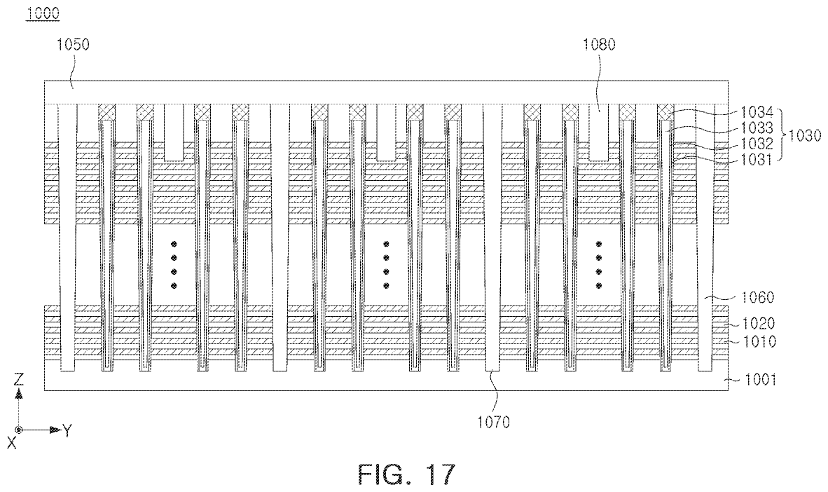

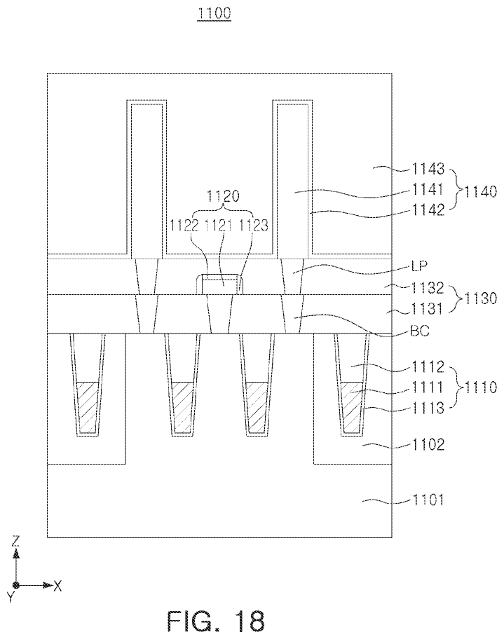

FIGS. 17 and 18 are views simply illustrating semiconductor devices to which an inspection operation using a semiconductor measurement apparatus according to an example implementation of the present disclosure may be applied.

First, referring to FIG. 17, an inspection operation using a semiconductor measurement apparatus according to an example implementation of the present disclosure is applied to a semiconductor device 1000, and the semiconductor device 1000 is a vertical memory device. The semiconductor device 1000 includes a plurality of gate electrode layers 1010 and a plurality of insulating layers 1020 stacked in a first direction (Z-axis direction), perpendicular to an upper surface of the substrate 1001, and channel structures CH extending in the first direction and penetrating through the gate electrode layers 1010 and the insulating layers 1020. An interlayer insulating layer 1050 is disposed on the plurality of gate electrode layers 1010, and the plurality of gate electrode layers 1010 are divided into a plurality of regions by separation layers 1060 and 1070. Meanwhile, some of the plurality of gate electrode layers 1010 are divided by an upper separation layer 1080.

Each of the channel structures CH may include a channel layer 1032 connected to a substrate 1001, a gate dielectric layer 1031 disposed between the channel layer 1032 and the gate electrode layers 1010, a buried insulating layer 1033 within the channel layer 1032, and a drain region 1034 on an upper portion of the channel layer 1032. The drain region 1034 may be connected to at least one of bit lines BL through a bit line contact 1035, and the bit lines BL may be connected to a page buffer formed in a peripheral circuit region PERI.

In a process of manufacturing the semiconductor device 1000, stack structures corresponding to the plurality of gate electrode layers 1010 and the plurality of insulating layers 1020 may be formed first, and channel structures CH extending to the substrate 1001 by penetrating through the stack structures may be formed. Therefore, it is necessary to accurately control a depth of a plurality of holes formed in the stack structure in a process of forming the channel structures CH. Furthermore, it is necessary to accurately control the depth thereof in a process of forming the separation layers 1060 and 1070 for dividing the plurality of gate electrode layers 1010 and the plurality of insulating layers 1020.

In order to control such a process, a semiconductor measurement apparatus according to an example implementation of the present disclosure may be used. As described above, in the semiconductor measurement apparatus according to an example implementation of the present disclosure, patterns formed in a sample may be restored into a result image having high resolution by irradiating the sample with light including a speckle pattern. Furthermore, by generating a phase image separately from the result image, a height or a depth of the pattern included in the sample may be accurately measured. A depth of a groove formed by an etching process of forming the channel structures CH or the separation layers 1060 and 1070 may be measured using the semiconductor measurement apparatus according to an example implementation of the present disclosure, thereby improving a yield of the manufacturing process of the semiconductor device 1000.

Next, referring to FIG. 18, an inspection operation using a semiconductor measurement apparatus according to an example implementation of the present disclosure is applied to a semiconductor device 1100, and the semiconductor device 1100 is a dynamic random access memory (DRAM) device. Referring to FIG. 18, the semiconductor device 1100 includes a substrate 1101 including a semiconductor material, a gate structure 1110, a bit line structure 1120, an interlayer insulating layer 1130, and a cell capacitor 1140. In the substrate 1101, a separation region 1102 for defining an active region is formed of an insulating material, and the gate structure 1110 is formed in a structure in which the substrate 1101 is embedded.

The gate structure 1110 may include a gate electrode layer 1111, a capping layer 1112, and a gate insulating layer 1113. According to some implementations, the gate electrode layer 1111 may have a multilayer structure formed of a plurality of different conductive materials, for example, metal materials, or may provide a word line. The capping layer 1112 may be formed of polysilicon, silicon nitride, silicon oxide, silicon oxynitride, silicon carbonitride, or silicon oxycarbonitride. The gate insulating layer 1113 may be formed of a high dielectric constant material having a higher dielectric constant than silicon oxide and silicon nitride. A channel region may be formed in a region of the substrate 1101 adjacent to the gate electrode layer 1111.

The interlayer insulating layer 1130 may be disposed on an upper portion of the substrate 1101. The interlayer insulating layer 1130 may include a lower interlayer insulating layer 1131 and an upper interlayer insulating layer 1132. The active region adjacent to the gate structure 1110 may be connected to a buried contact BC penetrating through the lower interlayer insulation layer 1131, and the buried contact BC may be connected to a landing pad LP penetrating through the upper interlayer insulation layer 1132. The buried contact BC connected to the active region between the gate structures 1110 adjacent to each other may be connected to the bit line structure 1120. The bit line structure 1120 may include a conductive layer 1121, a capping layer 1122, and a spacer 1123.

A cell capacitor 1140 extending in the first direction (Z-axis direction) may be connected to an upper portion of the landing pad LP. The cell capacitor 1140 may include a lower electrode 1141, a capacitor dielectric layer 1142, and an upper electrode 1143, and a shape of the lower electrode 1141 may have a different shape other than a pillar shape as illustrated in FIG. 18. The lower electrode 1141 may be formed of a metal and a metal compound, and the upper electrode 1143 may be formed of a doped semiconductor material, such as silicon germanium (SiGe).

In the process of manufacturing the semiconductor device 1100, for example, the buried contact BC may be formed by forming a groove by an etching process of removing a partial region of the first interlayer insulating layer 1131, and filling the groove with a conductive material. As the integration of the semiconductor device 1100 increases and a gap between the gate structures 1110 decreases, a location of the buried contact BC needs to be accurately specified and a width and a depth of the groove to form the buried contact BC need to be accurately controlled to prevent defects.

In order to control such an etching process, a semiconductor measurement apparatus according to an example implementation of the present disclosure may be used. As described above, in the semiconductor measurement apparatus according to an example implementation of the present disclosure, a high-resolution result image may be generated using light including a speckle pattern, and a depth and a width of the pattern included in the sample may be accurately measured using a phase image. A position, a width, and a depth of the groove for forming the buried contact BC may be measured using the semiconductor measurement apparatus according to an example implementation of the present disclosure, thereby improving a yield of the manufacturing process of the semiconductor device 1100.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

The present disclosure is not limited to the above-described implementations and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor measurement apparatus comprising:
a light source configured to output light in a predetermined wavelength band;
a pattern generator configured to scatter the light output from the light source to produce a speckled light pattern;
a stage arranged to receive the speckled light pattern from the pattern generator, wherein the stage is configured to support a sample in a position to reflect the speckled light pattern;
an image sensor positioned to receive the speckled light pattern reflected from the sample and to generate an original image representing a diffractive pattern of the speckled light pattern reflected from the sample; and
a controller configured to:
generate a prediction image for light incident on the image sensor using a first optical model representing optical characteristics of the speckled light pattern and a second optical model representing optical characteristics of a measurement region of the sample that reflects the speckled light pattern,
compare the prediction image with the original image, and
generate a result image representing the measurement region.

2. The semiconductor measurement apparatus of claim 1, further comprising:
a mirror configured to reflect the speckled light pattern from the sample to the image sensor.

3. The semiconductor measurement apparatus of claim 1, wherein the wavelength band includes at least one of an ultraviolet wavelength band, an extreme ultraviolet wavelength band, and a visible light wavelength band.

4. The semiconductor measurement apparatus of claim 1, wherein the speckled light pattern includes a plurality of planar waves oriented in different directions.

5. The semiconductor measurement apparatus of claim 1, wherein the controller is configured to optimize each of the first optical model and the second optical model by executing a backward propagation operation using a difference between the prediction image and the original image.

6. The semiconductor measurement apparatus of claim 1, wherein the controller is configured to optimize each of the first optical model and the second optical model to minimize a difference between the prediction image and the original image, and
wherein the result image is generated using the optimized first optical model and the optimized second optical model.

7. The semiconductor measurement apparatus of claim 6, wherein the controller is configured to:
obtain a phase image of light incident on the image sensor using the optimized first optical model, the optimized second optical model, or both the optimized first optical model and the optimized second optical model, and
determine physical properties of a layer included in the measurement region of the sample, a height of patterns formed in the measurement region of the sample, or both the physical properties and the height of the patterns, using the phase image.

8. The semiconductor measurement apparatus of claim 1, wherein the result image is an image representing a shape of patterns formed in the measurement region of the sample.

9. The semiconductor measurement apparatus of claim 1, wherein the controller is configured to move the stage so that the speckled light pattern is reflected from a plurality of unit regions in the measurement region of the sample, and
the image sensor is configured to generate a plurality of original images corresponding to the plurality of unit regions, and the controller is configured to generate a plurality of prediction images for light reflected from the plurality of unit regions and being incident on the image sensor.

10. The semiconductor measurement apparatus of claim 9, wherein at least two unit regions of the plurality of unit regions overlap.

11. The semiconductor measurement apparatus of claim 10, wherein the controller is configured to:
optimize the first optical model and the second optical model so that a difference between the plurality of prediction images and the plurality of original images is minimized and consistency between the plurality of prediction images is recognized, and
generate a plurality of result images for the plurality of unit regions, using the optimized first optical model and the optimized second optical model.

12. The semiconductor measurement apparatus of claim 9, wherein the controller is configured to apply different second optical models to at least two unit regions of the plurality of unit regions.

13. The semiconductor measurement apparatus of claim 1, further comprising:
a housing having a space in which the light source, the pattern generator, the stage, and the image sensor are disposed; and
a pump configured to maintain the space in a vacuum state.

14. A semiconductor measurement apparatus comprising:
a light source configured to output coherent light;
a pattern generator configured to emit light including a plurality of planar waves oriented in different directions to a sample by scattering the coherent light;
a stage configured to adjust a position of the sample so that light is reflected in a selection region, wherein the selection region is a partial region of the sample; and
an image sensor configured to generate an original image in response to the light reflected from the selection region.

15. The semiconductor measurement apparatus of claim 14, wherein the pattern generator includes at least one of a diffractive optical element, an optical lattice structure, a scattering element, and a wavefront modulator.

16. The semiconductor measurement apparatus of claim 14, wherein the original image is an image representing a diffractive pattern of light.

17. The semiconductor measurement apparatus of claim 16, further comprising:
a controller configured to:
generate a prediction image, for estimating diffractive characteristics of light incident on the image sensor, using a first optical model representing optical characteristics of light emitted by the pattern generator and a second optical model representing optical characteristics of the selection region,
optimize the first optical model and the second optical model using a difference between the prediction image and the original image, and
generate a result image representing a shape of structures included in the selection region using the first optical model, the second optical model, or both the first optical model and the second optical model.

18. The semiconductor measurement apparatus of claim 17, wherein the controller is configured to determine initial values of each optical model of the first optical model and the second optical model.

19. A semiconductor measurement apparatus comprising:
a speckle lighting configured to output light including a plurality of planar waves oriented in different directions;
a stage in which a sample for reflecting the light output from the speckle lighting is disposed;
an image sensor configured to generate an original image in response to light reflected from a partial region of the sample; and
a controller configured to:
generate a prediction image, for estimating a diffractive pattern of light incident on the image sensor, by executing a forward propagation operation with a first optical model representing optical characteristics of light output by the speckle lighting and a second optical model representing optical characteristics of the light reflected from the sample,
execute a backward propagation operation for adjusting the first optical model and the second optical model based on a difference between the prediction image and the original image, and
obtain a result image representing the partial region of the sample by repeatedly executing the forward propagation operation and the backward propagation operation.

20. The semiconductor measurement apparatus of claim 19, wherein the controller is configured to:
determine fidelity of the prediction image by applying the prediction image and the original image to a cost function, and
repeatedly execute the forward propagation operation and the backward propagation operation until the fidelity is equal to or smaller than a predetermined threshold.
